(19) United States
(12) Patent Application Publication
(10) Pub. No.: US 2018/0226515 A1
(43) Pub. Date: Aug. 9, 2018

(54) SEMICONDUCTOR DEVICE AND METHOD OF FORMING EMBEDDED THERMOELECTRIC COOLER FOR HEAT DISSIPATION OF IMAGE SENSOR

(71) Applicant: SEMICONDUCTOR COMPONENTS INDUSTRIES, LLC, Phoenix, AZ (US)

(72) Inventor: Oswald L. SKEETE, Phoenix, AZ (US)

(73) Assignee: SEMICONDUCTOR COMPONENTS INDUSTRIES, LLC, Phoenix, AZ (US)

(21) Appl. No.: 15/425,171

(22) Filed: Feb. 6, 2017

(51) Int. Cl. H01L 31/024; H01L 27/146

(52) U.S. Cl. CPC H01L 31/024; H01L 27/1469; H01L 27/14618; H01L 27/14636; H01L 27/14634

(57) ABSTRACT

A semiconductor device has a first substrate with a vertical electrical interconnect structure formed between opposing surfaces of the first substrate. A semiconductor die is embedded within the first substrate. A plurality of semiconductor pellets is disposed over or within the first substrate. A first semiconductor pellet is doped to a first conductivity type, and a second semiconductor pellet is doped to a second conductivity type. A second thermally conductive substrate is disposed over the semiconductor pellets opposite the first substrate. An image sensor is disposed over the first substrate. The image sensor is electrically connected through the vertical electrical interconnect structure of the first substrate. An encapsulant is deposited over the image sensor with an opening in the encapsulant over an active region of the image sensor. Electric current is enabled through the semiconductor pellets for heat dissipation of the image sensor.

### FIELD OF THE INVENTION

The present invention relates in general to semiconductor devices and, more particularly, to a semiconductor device and method of forming an embedded thermoelectric cooler for heat dissipation of an image sensor.

### BACKGROUND

An image sensor integrated circuit (IC) is a type of semiconductor device that detects and records an image by converting the variable attenuation of light waves or electromagnetic radiation into electric signals. An image sensor may include an array of imaging pixels. The imaging pixels include photosensitive elements, such as photodiodes, that convert the incoming image light into image signals. A typical image sensor can have hundreds of thousands or millions of pixels. The image sensor uses control circuitry to operate the imaging pixels and readout circuitry for reading out image signals corresponding to the electric charge generated by the photosensitive elements.

An image sensor can be implemented with semiconductor charge-coupled devices (CCD) and active pixel sensors in complementary metal-oxide-semiconductor (CMOS) or N-type metal-oxide-semiconductor (NMOS) technologies with applications in electronic devices, such as digital cameras, computers, cellular telephones, video recorders, automotive, medical imaging equipment, night vision equipment, thermal imaging devices, radar, sonar, and other image detecting devices that gather incoming image light to capture an image.

The image sensor IC typically has an electrical output even when no light is incident to the sensor, known as the sensor's dark current. A large dark current manifests as visual noise in output images and potentially overwhelms or degrades the output image signal. Therefore, manufacturers of image sensors seek to reduce dark current in the image sensor of an electronic device.

One significant factor contributing to dark current, and thus image noise, is the temperature of the image sensor IC. FIG. 1a illustrates graph 10 of dark current over a range of temperatures for a common CMOS image sensor. Graph 10 shows that dark current increases exponentially when the image sensor temperature rises above 50° C. However, in many cases the image sensor operates in conditions above 50° C. For instance, a vehicle operating in broad daylight and a hot climate can exceed 50° C. Manufacturers seek to implement measures to reduce the temperature of image sensor and keep the temperature below a desired threshold.

FIG. 1b illustrates a common configuration for an off-the-shelf thermoelectric cooler (TEC) 12. TEC 12 includes a cool-side plate 20 and warm-side plate 22. A plurality of positively doped (P-doped) semiconductor pellets 32 and negatively doped (N-doped) semiconductor pellets 34 are electrically coupled in series by conductive traces 36 on plates 20 and 22. As electric current flows between the differing conduction types between P-doped semiconductor pellets 32, N-doped semiconductor pellets 34, and conductive traces 36 in series, the electrons flowing through TEC 12 remove heat energy from cool-side plate 20 and deposit heat energy in warm-side plate 22 through the Peltier effect. An electrical signal is applied to terminals 36 and 38 to enable the cooling effect of TEC 12.

An image sensor IC could be mounted on cool plate 20 of TEC 12 to help control the temperature of the image sensor. However, TEC configurations available on the market are large and expensive, which makes the resulting end products non-cost effective. Using TEC 12 with an image sensor potentially increases performance by keeping the image sensor IC cool, but results in an end product that is overly expensive and undesirably large.

Accordingly, a need exists for an embedded and integrated thermoelectric cooler for use in semiconductor packages with an image sensor and other semiconductor components.

### BRIEF DESCRIPTION OF THE DRAWINGS

FIGS. 1a-1b illustrate dark current of an image sensor IC over a range of temperatures, and a conventional thermoelectric cooler;

FIGS. 2a-2g illustrate a process of forming an image sensor package with an integrated thermoelectric cooler;

FIG. 3 illustrates an image sensor semiconductor package with an integrated thermoelectric cooler;

FIGS. 4a-4b illustrate an embodiment of a thermoelectric cooler embedded in an image sensor semiconductor substrate package;

FIGS. 5a-5d illustrate another embodiment of forming a thermoelectric cooler embedded in an image sensor semiconductor substrate package;

FIG. 6 illustrates another embodiment of a thermoelectric cooler embedded in an image sensor semiconductor substrate package; and

FIGS. 7a-7b illustrate an electronic device containing the image sensor semiconductor substrate package.

### DETAILED DESCRIPTION OF THE DRAWINGS

The following describes one or more embodiments with reference to the figures, in which like numerals represent the same or similar elements. While the figures are described in terms of the best mode for achieving certain objectives, the description is intended to cover alternatives, modifications, and equivalents as may be included within the spirit and scope of the disclosure. The term “semiconductor die” as used herein refers to both the singular and plural form of the words, and accordingly, can refer to both a single semiconductor device and multiple semiconductor devices. The term “image sensor” refers both to a sensor associated with an individual pixel, as well as to a sensor associated with a plurality or array of pixels.

An image sensor uses a pixel to capture light in a given environment and generate an electrical signal representative of an image in the environment. For example, electrical signals generated by the pixel generate a digital image, which is presented as information to a user of an electronic device. In some suitable scenarios, electrical signals generated by the image sensor is processed and used to capture information regarding the light that is received at the image sensor, such as brightness, wavelength, spatial patterning, temporal patterning, polarization, direction, and other suitable characteristics associated with light. Such light characteristics can be modified by a light-emitting or reflecting source to encode information based on the characteristics of the light.

Electronic devices, such as digital cameras, computers, cellular telephones, automotive, video recorders, medical imaging equipment, night vision equipment, thermal imaging devices, radar, sonar, and other image detecting devices gather incoming image light to capture an image. The image sensor includes arrays of image pixels. The imaging pixels include photosensitive elements, such as photodiodes, that convert the incoming image light into image signals. A typical image sensor can have hundreds of thousands or millions of pixels. The image sensor uses control circuitry to operate the imaging pixels and readout circuitry for reading out image signals corresponding to the electric charge generated by the photosensitive elements.

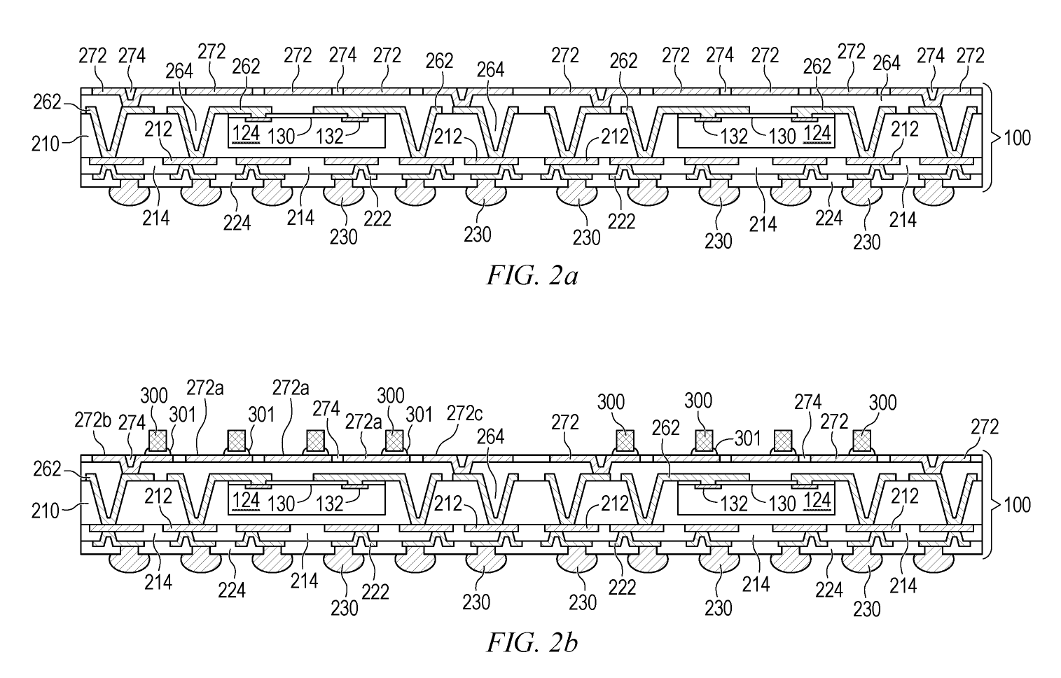

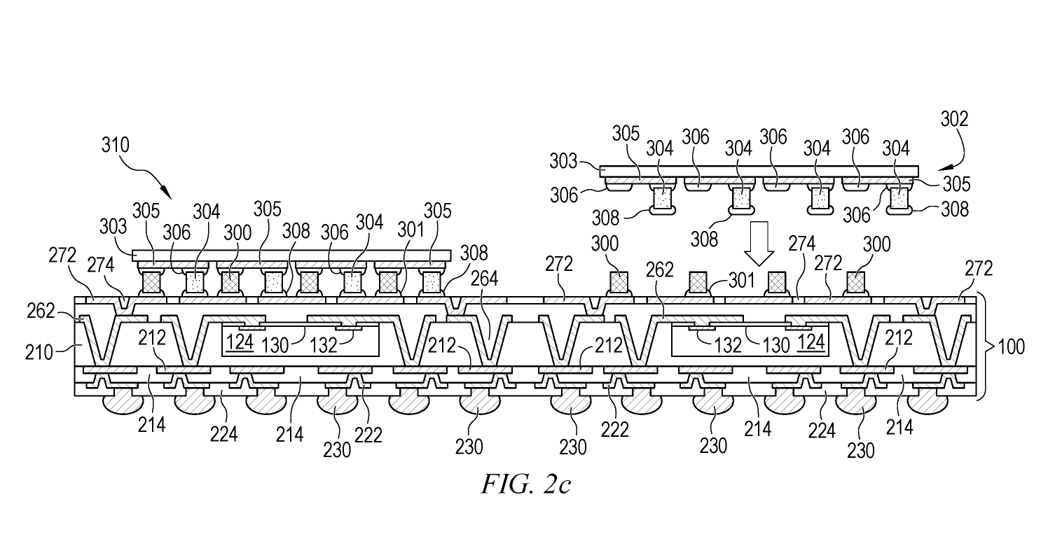

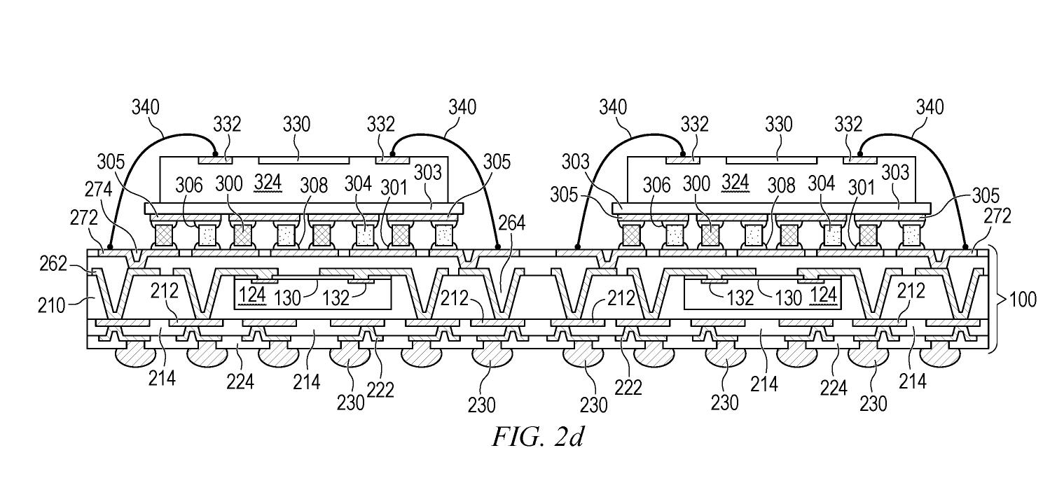

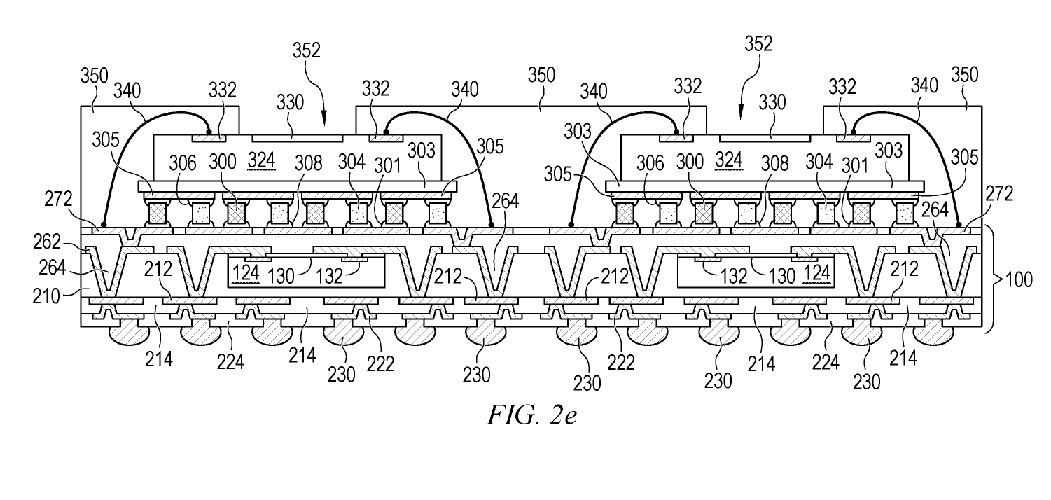

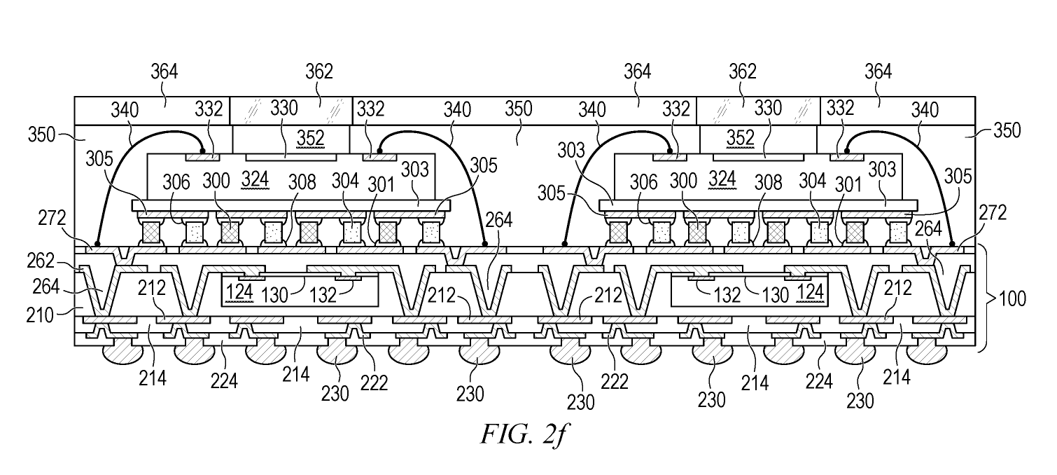

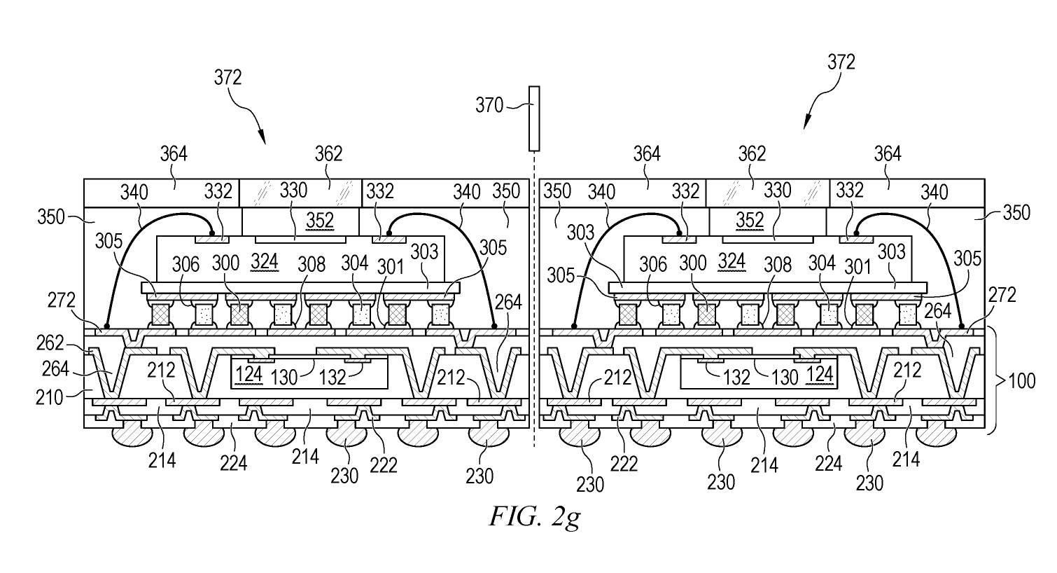

FIG. 2a shows a cross-sectional view of substrate 100 with embedded semiconductor die 124 having active surface 130 and contact pads 132, and encapsulant or molding compound 210 deposited over semiconductor die 124. An electrically conductive layer 212 is formed over encapsulant 210. An insulating or passivation layer 214 is formed over encapsulant 210 and conductive layer 212. An electrically conductive layer 222 is formed over insulating layer 214 and conductive layer 212. Portions of conductive layers 212 and 222 can be electrically common or electrically isolated depending on the design and function of semiconductor die 124, and operate as an RDL to fan-out and extend electrical connection for external interconnection. An insulating or passivation layer 224 is formed over insulating layer 214 and conductive layer 222. Bumps 230 are formed over conductive layer 222.

A portion of encapsulant 210 is removed and an electrically conductive layer 262 is formed over the encapsulant extending to conductive layer 212. An insulating or passivation layer 264 is formed over encapsulant 210 and conductive layer 262. An electrically conductive layer 272 is formed over insulating layer 264. An insulating or passivation layer 274 is formed over insulating layer 264 and conductive layer 272. The combination of conductive layers 212, 222, 262, and 272, and bumps 230 constitute a vertical electrical interconnect structure between opposing surfaces of substrate 100.

Substrate 100 represents one type of substrate with a vertical electrical interconnect structure and embedded semiconductor die 124. Additional embodiments of the substrate include other configurations of the vertical electrical interconnect structure with or without the embedded semiconductor die.

In FIG. 2b, a plurality of P-doped semiconductor pellets 300 is disposed on conductive layer 272 using a pick-and place operation. P-doped semiconductor pellets 300 are mounted to conductive layer 272 by solder paste or other conductive material 301. In some embodiments, solder paste 301 is reflowed to create an electrical and metallurgical bond between P-doped semiconductor pellets 300 and conductive layer 272. Each centrally located portion 272a of conductive layer 272 has one P-doped semiconductor pellet 300 to carry electrical current down to conductive layers 262 and 272, and will later have an N-doped semiconductor pellet 304 as the return path to an upper conductive layer. Portion 272b of conductive layer 272 has a P-doped semiconductor pellet 300 and is electrically connected to semiconductor die 124 through conductive layer 262 as the final return path for electrical current through the TEC. Other portions of conductive layer 272, not illustrated, connect between conductive layer 262 and image sensor IC 324 without coupling to semiconductor pellets 300 and 304.

In FIG. 2c, a top half 302 of the TEC is disposed over substrate 100 and P-doped semiconductor pellets 300. Each top half 302 includes thermally conductive substrate 303 implemented as a ceramic plate or heat spreader. A conductive layer 305 is patterned over substrate 303. An N-doped semiconductor pellet 304 is disposed on each portion of conductive layer 305, and room is reserved for P-doped semiconductor pellets 300 on substrate 100. Solder paste or other conductive material 306 is disposed on conductive layer 305 to hold N-doped semiconductor pellets 304 onto top half 302 while mounting the top half over substrate 100. Other portions of solder paste 306 remain devoid of N-doped semiconductor pellets 304 to accommodate P-doped semiconductor pellets 300. Solder paste 308 is disposed over N-doped semiconductor pellets 304 to connect the N-doped semiconductor pellets to conductive layer 272. In some embodiments, solder paste 308 is disposed on substrate 100 along with solder paste 301, as shown in FIG. 2b.

N-doped semiconductor pellets 304 are affixed to substrate 303 and then disposed over substrate 100 between P-doped semiconductor pellets 300, which are already mounted onto substrate 100. Alternatively, P-doped semiconductor pellets 300 are affixed to substrate 303 and then disposed over substrate 100 between N-doped semiconductor pellets 304, which are already mounted onto substrate 100. In some embodiments, all P-doped semiconductor pellets 300 and all N-doped semiconductor pellets 304 are disposed over substrate 100 or substrate 303, followed by mounting the opposite substrate (303 or 100) over semiconductor pellets 300 and 304.

Once top half 302 is disposed on substrate 100, solder paste 301, 306, and 308 are reflowed to metallurgically and electrically connect P-doped semiconductor pellets 300 and N-doped semiconductor pellets 304 to conductive layers 305 and 272. The left side of FIG. 2c illustrates a completed TEC 310 formed over substrate 100. Each P-doped semiconductor pellet 300 and N-doped semiconductor pellet 304 are electrically coupled in series by conductive layers 272 and 305. One N-doped semiconductor pellet 304 is disposed on portion 272c of conductive layer 272 as the source of electrical current from semiconductor die 124. From the right side of substrate 303, an electric current flows in portion 272c of conductive layer 272, up semiconductor pellet 304, across conductive layer 305, down semiconductor pellet 300, across portion 272a of conductive layer 272, up semiconductor pellet 304, across conductive layer 305, down semiconductor pellet 300, and the path repeats across TEC 310 terminating in portion 272b of conductive layer 272. As electrical current flows through P-doped semiconductor pellets 300 and N-doped semiconductor pellets 304, thermal energy is transferred from substrate 303 to substrate 100. In some embodiments, a transistor or other electronic switch embedded in or disposed on substrate 100 is used to control electrical current through TEC 310. While a single line of semiconductor pellets 300 and 304 is illustrated as coupled in series, other embodiments of TEC 310 include a two-dimensional array of oppositely doped semiconductor pellets electrically coupled in series.

In FIG. 2d, image sensor ICs 324 are disposed on substrate 303. Image sensor ICs 324 include image sensor region 330 with one or more light reactive sensors, such as photodiodes or phototransistors, having the ability to generate or control the flow of electrical current in response to an external light stimulus. In one embodiment, sensor region 330 includes a CCD for capturing an image.

Image sensor IC 324 includes a plurality of contact pads 332 on the active surface opposite substrate 303. Image sensor IC 324 is electrically connected to substrate 100 by bond wires 340 extending from conductive layer 272 to contact pads 332. Bond wires 340 are mechanically and electrically coupled to conductive layer 272 and contact pads 332 by thermocompression bonding, ultrasonic bonding, wedge bonding, stitch bonding, ball bonding, or other suitable bonding technique. Bond wires 340 include a conductive material, such as Cu, Al, Au, Ag, or a combination thereof. Semiconductor die 124 communicates with image sensor IC 324 through conductive layer 262, conductive layer 272, and bond wires 340 to control the image sensor and receive data representing a captured image.

In FIG. 2e, an encapsulant or molding compound 350 is deposited over substrate 100, TEC 310, image sensor IC 324, and bond wires 340 as an insulating material using a paste printing, compressive molding, transfer molding, liquid encapsulant molding, vacuum lamination, spin coating, or other suitable applicator. Encapsulant 350 can be polymer composite material, such as epoxy resin with filler, epoxy acrylate with filler, or polymer with proper filler. Encapsulant 350 is non-conductive and environmentally protects the semiconductor device from external elements and contaminants.

An area over image sensor region 330 remains devoid of encapsulant 350 to allow light to pass to the image sensor region without significant interference. In some embodiments, a mask is disposed on image sensor region 330 prior to depositing encapsulant 350, and then removed after depositing the encapsulant to form opening 352 and leave image sensor region 330 exposed. In other embodiments, encapsulant 350 is deposited to completely cover image sensor IC 324, and then a portion over image sensor region 330 is removed by etching, laser direct ablation (LDA), or another suitable process to form opening 352.

In one embodiment, IC 324 is a semiconductor die without not an image sensor, but still needing the heat dissipation properties of TEC 310. In embodiments where IC 324 does not include an image sensor, encapsulant 350 may fully cover IC 324 to complete the package.

In FIG. 2f, lens 362 is disposed over opening 352 to assist with focus or otherwise condition an image prior to capture by image sensor region 330. Lens 362 includes an optically transparent or translucent glass or plastic material. In one embodiment, lens 362 is formed from optical grade polyimide. An insulating layer 364 is deposited over encapsulant 350 and around lens 362 to hold the lens in place over image sensor region 330 and encapsulant 350.

In some embodiments, encapsulant 350 and insulating layer 360 are deposited over image sensor IC 324 and substrate 100 in a single step, and form a single uniform body of insulating material. A two-stage opening is formed that is wider at the top to accommodate lens 362 and narrower at the bottom to properly space lens 362 away from image sensor region 330. Insulating layer 364 is formed first in some embodiments, and then lens 362 is disposed in an opening of the insulating layer. An additional adhesive is optionally used to hold lens 362 in insulating layer 360 and on encapsulant 350.

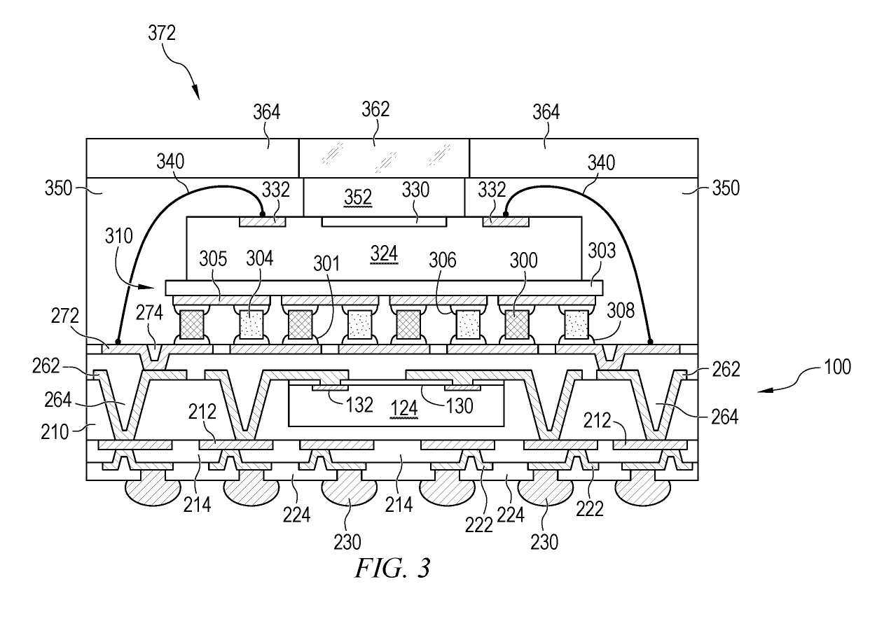

In FIG. 2g, semiconductor die 124 and 324 are singulated through insulating layer 360, encapsulant 350, and substrate 280 by saw blade or laser cutting tool 370 to provide individual image sensor semiconductor package 372. FIG. 3 illustrates a final image sensor package 372 after singulation. Light travels through lens 362 and opening 352 to image sensor region 330. Image sensor region 330 includes a CCD or other image capturing circuit. Image sensor region 330 communicates captured data to semiconductor die 124 through bond wires 340, conductive layer 272, and conductive layer 262. Image sensor package 372 is integrated into a larger electronic device by mounting the package onto another substrate with bumps 230.

Semiconductor die 124 includes active functionality to process data from image sensor region 330 and output a usable image file or other desired data. Semiconductor die 124 outputs usable data to a central processing unit (CPU) or other component of the larger electronic device through conductive layer 262, conductive layer 212, conductive layer 222, and conductive bumps 230. In one embodiment, some bumps 230 are directly connected to image sensor IC 324 by conductive layers 222, 212, 262, and 272, and bond wires 340 for testing sensor region 330 or other purposes.

Image sensor IC 324 with image sensor region 330 is disposed on substrate 303 of TEC 310 within image sensor package 372. TEC 310 includes a plurality of P-doped semiconductor pellets 300 and N-doped semiconductor pellets 304 coupled electrically in series and thermally in parallel between substrate 100 and substrate 303. An electric current through serially connected P-doped semiconductor pellets 300 and N-doped semiconductor pellets 304 creates a temperature gradient that transfers heat away from image sensor IC 324, cooling the image sensor IC to reduce the impact of dark current caused by elevated temperatures. TEC 310 further dissipates heat generated by semiconductor die 124. Image sensor region 330 captures accurate images with a reduction in the amount of image noise that accompanies dark current at higher temperatures.

In some embodiments, current through TEC 310 is controlled by semiconductor die 124. Semiconductor die 124 receives feedback from a temperature image sensor on image sensor IC 324 or embedded elsewhere in package 372. As long as image sensor IC 324 is at or below 50° C., or another desired threshold, semiconductor die 124 disables current through TEC 310 to reduce energy usage when heat dissipation is not needed. Once the temperature of image sensor IC 324 is detected at or above the relevant threshold, semiconductor die 124 turns on TEC 310 to keep image sensor IC 324 cool. The thermostat functionality can be integrated into image sensor IC 324, semiconductor die 124, or a separate temperature controller chip may be included as part of package 372.

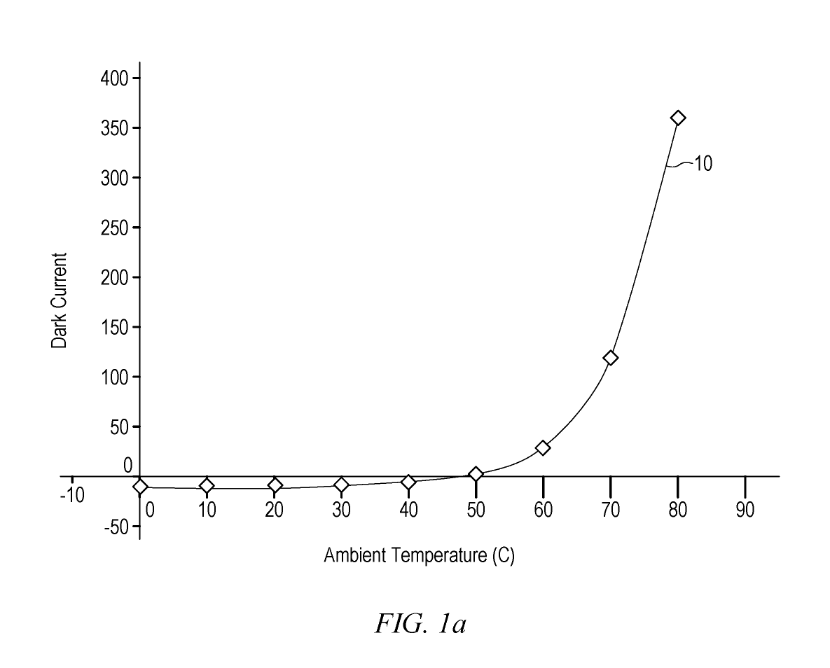

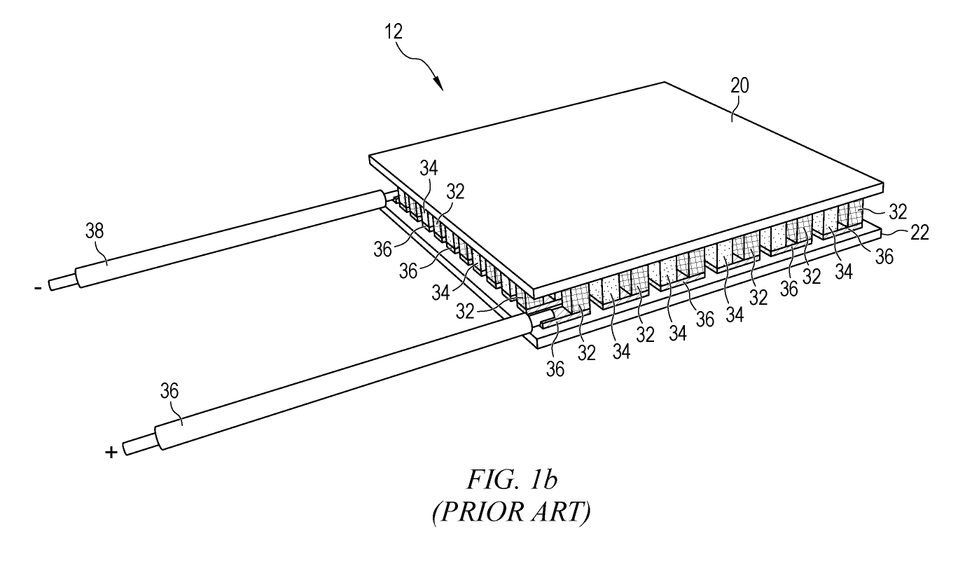

Because TEC 310 is formed directly on substrate 100, with substrate 100 operating as the lower plate of the TEC, the Peltier effect's heat dissipation benefit is provided without the larger size and expense of the conventional discrete TEC 12 from FIG. 1b. TEC 310 is an integrated and embedded thermoelectric cooler for heat dissipation of the image sensor and other integrated circuits.

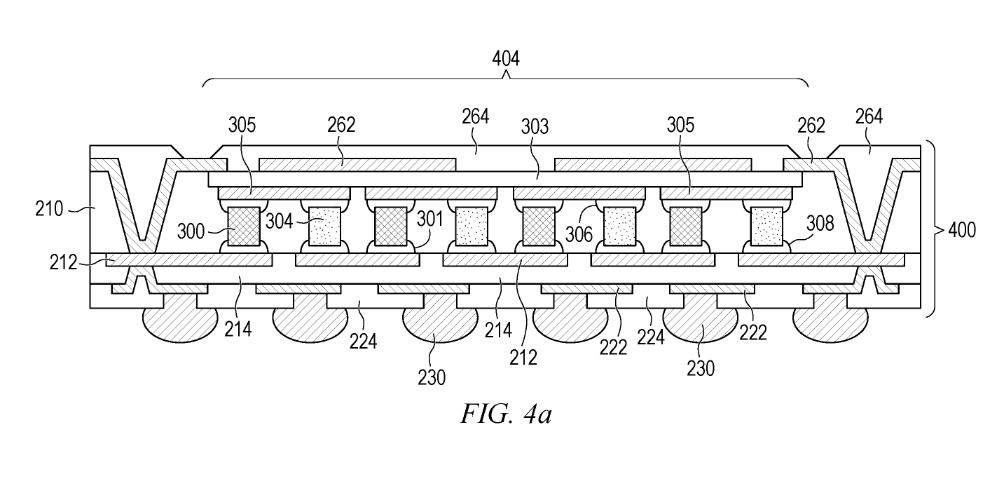

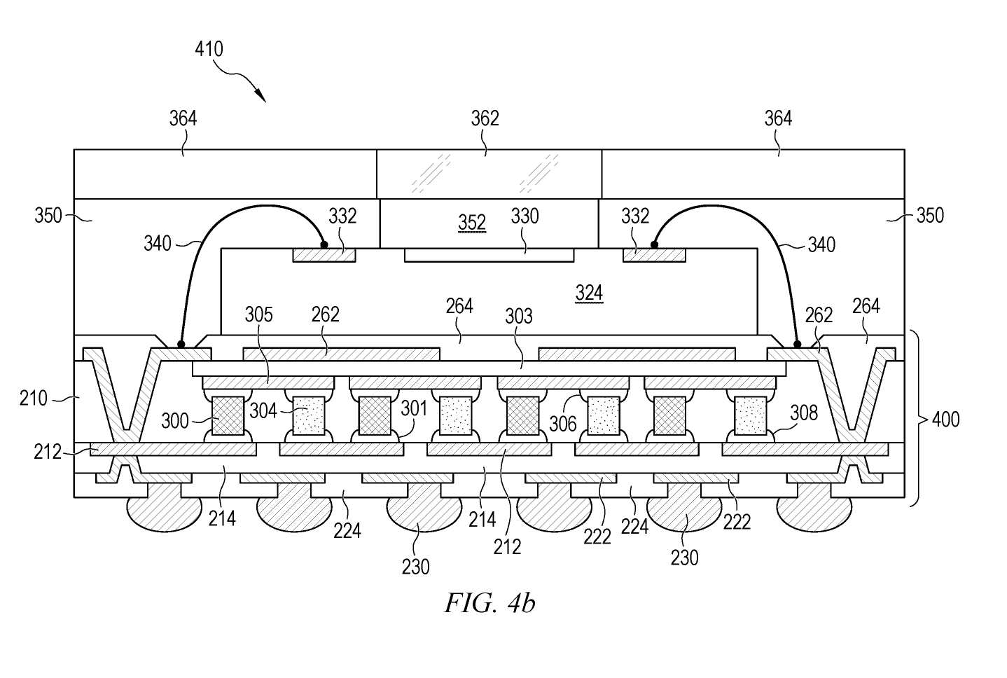

FIG. 4a illustrates a substrate 400 with an embedded TEC 404. Substrate 400 includes P-doped semiconductor pellets 300 and N-doped semiconductor pellets 304 within encapsulant 210 to form TEC 404 embedded in the substrate along with or in place of semiconductor die 124. Substrate 400 can be any type of printed circuit board (PCB) or other substrate with a vertical interconnect structure and thermoelectric cooler built as a part of forming the substrate. Conductive layer 212 is also used to couple P-doped semiconductor pellets 300 and N-doped semiconductor pellets 304 in series and route electrical current through TEC 404. The combination of conductive layers 212, 222, and 262, and bumps 230 constitute a vertical electrical interconnect structure between opposing surfaces of substrate 400.

In other embodiments, additional conductive and insulating layers are formed successively over either side of TEC 404 as desired to enable more complex electrical routing. Conductive layer 262 extends into an opening formed through encapsulant 210 to electrically couple conductive layer 262 and 212. In other embodiments, separate conductive vias are formed through encapsulant 210, and conductive layer 262 lies flat across a top surface of encapsulant 210.

FIG. 4b illustrates the finished image sensor package 410, formed similarly as shown in FIGS. 2b-2g. Image sensor IC 324 is disposed directly on substrate 400, or a thermal interface material or die attach adhesive is used between the image sensor IC and substrate in some embodiments. TEC 404 pulls thermal energy from image sensor IC 324 to the bottom of the package toward bumps 230. Substrate 303 is optional, and spreads the thermal energy laterally so that heat dissipation is relatively even across package 410.

Image sensor package 410 is mounted on a substrate by bumps 230 to integrate the functionality of image sensor IC 324 into the larger system. Image sensor IC 324 generates raw image data and transfers the data through bond wires 340 to conductive layer 262. In some embodiments, semiconductor die 124 is embedded in substrate 400 in another cross-sectional view. The raw image data from image sensor IC 324 is transferred through conductive layer 262, and potentially conductive layer 212, to be processed by semiconductor die 124. In other embodiments, raw data from image sensor IC 324 is transferred directly off of image sensor package 410 through bumps 230 to be processed by an active component in a separate package.

From the right side of substrate 303, an electric current flows in conductive layer 212, up semiconductor pellet 304, across conductive layer 305, down semiconductor pellet 300, across conductive layer 212, up semiconductor pellet 304, across conductive layer 305, down semiconductor pellet 300, and the path repeats across TEC 404. The electric current through serially connected P-doped semiconductor pellets 300 and N-doped semiconductor pellets 304 creates a temperature gradient that transfers heat away from image sensor IC 324, cooling the image sensor IC to reduce the impact of dark current caused by elevated temperatures. Image sensor region 330 captures accurate images with a reduction in the amount of image noise that accompanies dark current at higher temperatures. Because TEC 404 is embedded or formed within substrate 400, the Peltier effect's heat dissipation benefit is provided without the larger size and expense of the conventional discrete TEC 12 from FIG. 1b. TEC 404 is an integrated and embedded thermoelectric cooler for heat dissipation of the image sensor and other integrated circuits.

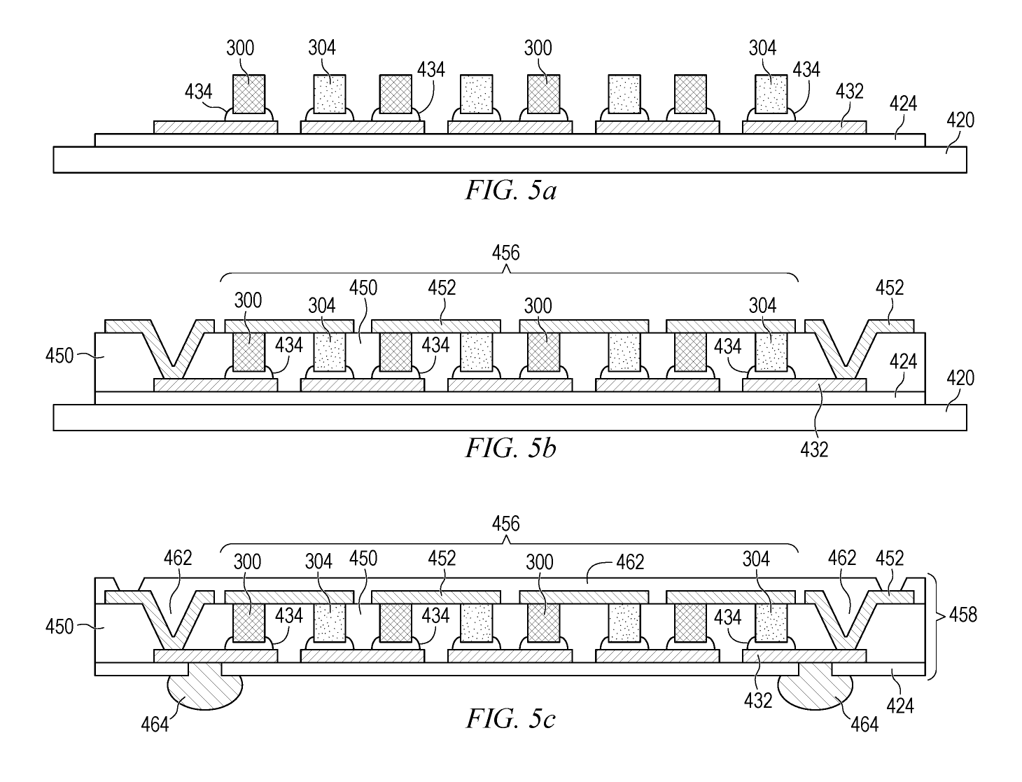

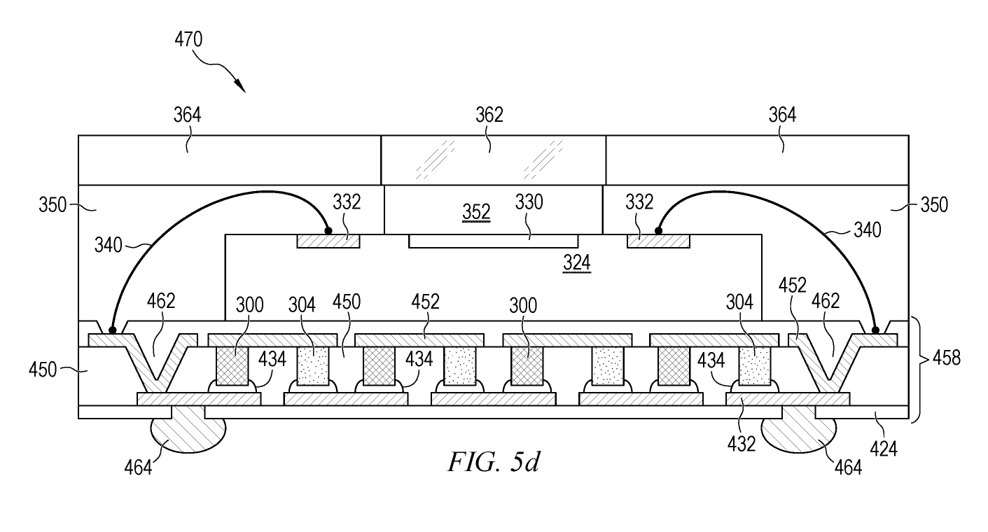

FIGS. 5a-5d illustrate forming a substrate with an embedded TEC without substrate 303. In FIG. 5a, insulating layer 424 is formed over carrier 420. Conductive layer 432 is deposited and patterned on insulating layer 424. Conductive layer 432 is patterned similarly to conductive layer 272 in FIG. 2a to couple P-doped semiconductor pellets 300 and N-doped semiconductor pellets 304 in series and route other electrical signals in the final package. P-doped semiconductor pellets 300 and N-doped semiconductor pellets 304 are disposed onto conductive layer 432 with solder paste or other conductive material 434 providing electrical and mechanical coupling.

In FIG. 5b, encapsulant 450 is deposited over substrate 420, conductive layer 434, and semiconductor pellets 300 and 304 similarly to encapsulant 210. Semiconductor pellets 300 and 304 are exposed through a top surface of encapsulant 450. In some embodiments, a mold used to deposit encapsulant 450 prevents the encapsulant from flowing over semiconductor pellets 300 and 304. In other embodiments, a planarization process is used to expose semiconductor pellets 300 and 304 after depositing encapsulant 450. Conductive layer 452 is deposited and patterned over encapsulant 450 and semiconductor pellets 300 and 304, including extending into openings through encapsulant 450 to contact conductive layer 432. Conductive layer 452 is deposited directly on semiconductor pellets 300 and 304. In some embodiments, a conductive material is plated or deposited over semiconductor pellets 300 and 304 prior to conductive layer 452 to help with mechanical adhesion and electrical connection. Conductive layer 452, along with conductive layer 432, couples semiconductor pellets 300 and 304 in series with alternating conductivity types along the signal path to form TEC 456.

FIG. 5c illustrates a completed substrate 458 with embedded TEC 456. An insulating or passivation layer 462 is deposited over conductive layer 452 and encapsulant 450. Carrier 420 is removed by chemical etching, mechanical peeling, or another appropriate method. Openings are formed through insulating layer 424 to expose conductive layer 432, and through insulating layer 462 to expose conductive layer 452, for subsequent electrical interconnection. Conductive bumps 464 are deposited in the openings of insulating layer 424 for mounting the final package including substrate 458 onto another substrate as part of a larger electronic device. The combination of conductive layers 432 and 452, and bumps 464 constitute a vertical electrical interconnect structure between opposing surfaces of substrate 458.

Image sensor package 470 is completed in FIG. 5d by mounting image sensor IC 324 over substrate 458. Image sensor IC 324 is coupled to conductive layer 452 by bond wires 340 extending through openings in insulating layer 462. Electrical signals are routed to and from image sensor IC 324 to semiconductor die 124, either within substrate 458 or elsewhere in the larger electronic device, by conductive layers 452 and 432. If formed as a panel, a plurality of image sensor packages 470 is formed together and singulated through insulating layer 360, encapsulant 350, and substrate 458. Image sensor packages 470 are mounted onto a substrate of a larger electronic device by reflowing bumps 464 between conductive layer 432 and a conductive layer of the external substrate.

An electric current flows in conductive layer 432, up semiconductor pellet 304, across conductive layer 452, down semiconductor pellet 300, across conductive layer 432, up semiconductor pellet 304, across conductive layer 452, down semiconductor pellet 300, and the path repeats across TEC 456. The electric current through serially connected P-doped semiconductor pellets 300 and N-doped semiconductor pellets 304 creates a temperature gradient that transfers heat away from image sensor IC 324, cooling the image sensor IC to reduce the impact of dark current caused by elevated temperatures. Image sensor region 330 captures accurate images with a reduction in the amount of image noise that accompanies dark current at higher temperatures. Because TEC 456 is formed within substrate 100, the Peltier effect's heat dissipation benefit is provided without the larger size and expense of the conventional discrete TEC 12 from FIG. 1b. TEC 456 is an integrated and embedded thermoelectric cooler for heat dissipation of the image sensor and other integrated circuits.

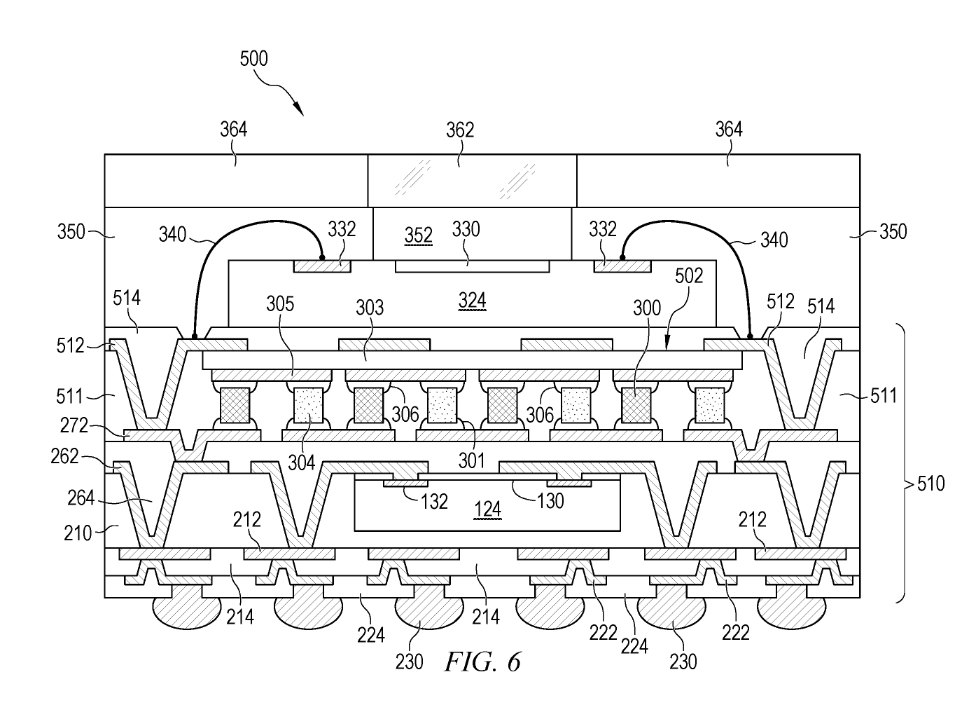

FIG. 6 illustrates an image sensor package 500 with TEC 502 stacked vertically over semiconductor die 124 within substrate 510. Substrate 510 includes insulating layer 511 formed over conductive layer 272 and insulating layer 274 and around TEC 502. Conductive layer 512 is deposited and patterned over insulating layer 511 and TEC 502. Insulating layer 514 is deposited over conductive layer 512 to complete substrate 510. Image sensor package 500 is formed similarly to image sensor package 372 in FIG. 3, but substrate formation continues after disposing the top half 302 on conductive layer 272 and P-doped semiconductor pellets 300 rather than immediately disposing image sensor IC 432 on substrate 303. Image sensor IC 324 is later disposed onto the completed substrate 510 including both TEC 502 and semiconductor die 124 embedded in the substrate. Bond wires 340 extend from contact pads 332 of image sensor IC 324 to conductive layer 512.

An electric current through serially connected P-doped semiconductor pellets 300 and N-doped semiconductor pellets 304 creates a temperature gradient that transfers heat away from image sensor IC 324, cooling the image sensor IC to reduce the impact of dark current caused by elevated temperatures. Image sensor region 330 captures accurate images with a reduction in the amount of image noise that accompanies dark current at higher temperatures. Because TEC 502 is embedded or formed within substrate 510, the Peltier effect's heat dissipation benefit is provided without the larger size and expense of the conventional discrete TEC 12 from FIG. 1b. TEC 502 is an integrated and embedded thermoelectric cooler for heat dissipation of the image sensor and other integrated circuits.

The above embodiments integrate or embed the function of a thermoelectric cooler on or within a substrate to provide heat dissipation of an image sensor or another device that might benefit from cooling. Reduced cooler size and cost allow integration of thermoelectric coolers into smaller and cheaper semiconductor packages and electronic devices.

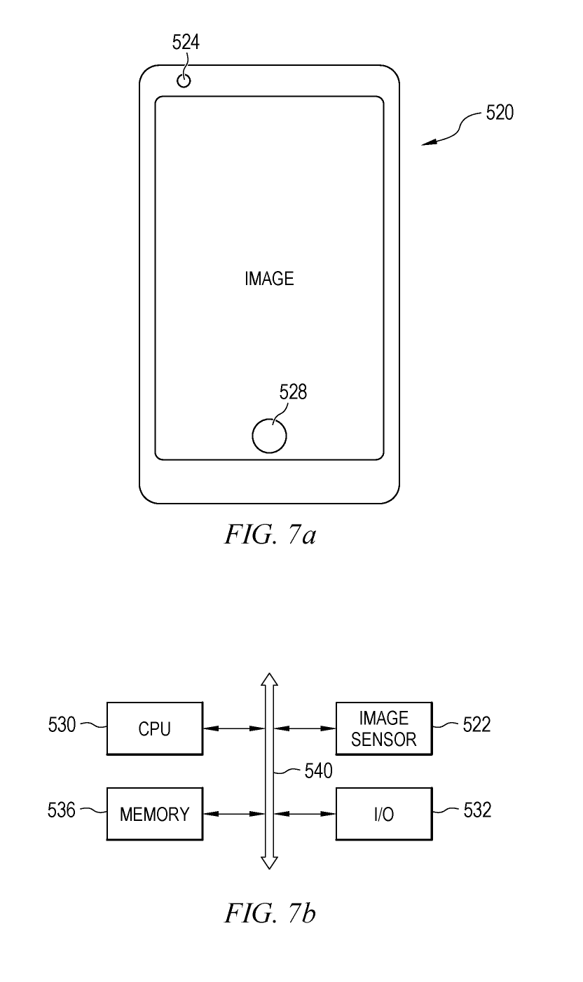

FIGS. 7a-7b show electronic device 520, such as a cellular phone with an internal camera, which includes an image sensing device 522 implemented with a semiconductor package, as described in FIGS. 2-6. FIG. 7a represents the cellular phone with camera. FIG. 7b is a functional block diagram of components within electronic device 520. Electronic device 520 includes lens 524 for focusing an image on the pixel array within image sensing device 522 when a shutter release button 528 is touched or pressed. In addition, electronic device 520 includes CPU 530, such as a microprocessor, to control camera and image processing functions, input/output (I/O) device 532, and memory 536, which communicate with CPU 530 over bus 540.

While one or more embodiments have been illustrated and described in detail, the skilled artisan will appreciate that modifications and adaptations to those embodiments may be made without departing from the scope of the present disclosure.

1-6. (canceled)

7. A method of making a semiconductor device with an image sensor, comprising:
providing a first substrate including a vertical electrical interconnect structure formed through the first substrate;
disposing a plurality of semiconductor pellets over the first substrate; and
disposing an image sensor over the first substrate, wherein the image sensor is electrically connected to the vertical electrical interconnect structure of the first substrate.

8. The method of claim 7, further including disposing a second substrate over the semiconductor pellets opposite the first substrate.

9. The method of claim 8, wherein the second substrate is thermally conductive.

10. The method of claim 7, wherein a first semiconductor pellet of the plurality of semiconductor pellets is doped to a first conductivity type and a second semiconductor pellet of the plurality of semiconductor pellets is doped to a second conductivity type.

11. The method of claim 7, further including depositing an encapsulant over the image sensor with an opening in the encapsulant over an active region of the image sensor.

12. The method of claim 7, further including providing a conduction path through the semiconductor pellets for heat dissipation of the image sensor.

13. The method of claim 7, further including disposing a semiconductor die embedded within the first substrate.

14. An image sensor semiconductor package, comprising:
a first substrate including a vertical electrical interconnect structure formed through the first substrate;
a plurality of semiconductor pellets disposed over the first substrate; and
an image sensor disposed over the first substrate, wherein the image sensor is electrically connected to the vertical electrical interconnect structure of the first substrate.

15. The image sensor semiconductor package of claim 14, further including a second substrate disposed over the semiconductor pellets opposite the first substrate.

16. The image sensor semiconductor package of claim 15, wherein the second substrate is thermally conductive.

17. The image sensor semiconductor package of claim 14, wherein a first semiconductor pellet of the plurality of semiconductor pellets is doped to a first conductivity type and a second semiconductor pellet of the plurality of semiconductor pellets is doped to a second conductivity type.

18. The image sensor semiconductor package of claim 14, further including an encapsulant deposited over the image sensor with an opening in the encapsulant over an active region of the image sensor.

19. The image sensor semiconductor package of claim 14, further including a conduction path through the semiconductor pellets for heat dissipation of the image sensor.

20. The image sensor semiconductor package of claim 14, further including a semiconductor die embedded within the first substrate.

21. A semiconductor device with an image sensor, comprising:
a first substrate including a vertical electrical interconnect structure formed between opposing surfaces of the first substrate;
a first semiconductor pellet disposed over the first substrate;
a second semiconductor pellet disposed over the first substrate; and
an image sensor disposed over the first substrate, wherein the image sensor is electrically connected through the vertical electrical interconnect structure of the first substrate.

22. The semiconductor device of claim 21, further including a second substrate disposed over the first semiconductor pellet and second semiconductor pellet opposite the first substrate.

23. The semiconductor device of claim 22, wherein the second substrate is thermally conductive.

24. The semiconductor device of claim 21, wherein the first semiconductor pellet is doped to a first conductivity type and the second semiconductor pellet is doped to a second conductivity type.

25. The semiconductor device of claim 21, further including an encapsulant deposited over the image sensor with an opening in the encapsulant over an active region of the image sensor.

26. The semiconductor device of claim 21, further including a semiconductor die embedded within the first substrate.
